(19) United States
(12) Patent Application Publication
(10) Pub. No.: US 2025/0130470 A1
(43) Pub. Date: Apr. 24, 2025

(54) ARRAY SUBSTRATE AND DISPLAY PANEL

(71) Applicant: Shenzhen China Star Optoelectronics Semiconductor Display Technology Co., Ltd., Shenzhen (CN)

(72) Inventor: Wenxiong ZHONG, Shenzhen (CN)

(73) Assignee: Shenzhen China Star Optoelectronics Semiconductor Display Technology Co., Ltd., Shenzhen (CN)

(21) Appl. No.: 18/541,133

(22) Filed: Dec. 15, 2023

(30) Foreign Application Priority Data
Oct. 18, 2023 (CN) 202311357636.7

(51) Int. Cl. G02F 1/1362; G02F 1/1339

(52) U.S. Cl. CPC G02F 1/136286; G02F 1/1339

(57) ABSTRACT

An embodiment of the present application discloses an array substrate and a display panel. In the array substrate, second line segment includes a connection portion and a wiring portion. The second signal line includes a third line segment. The third line segment and second line segment are in the same layer and are disposed adjacently on a first insulation layer. The third line segment is connected to a gate driver circuit unit, connection portion is connected to a first line segment. The wiring portion is connected to the connection portion and the gate driver circuit unit. A second insulation layer covers the first insulation layer, the third line segment, and the second line segment. A barrier wall is disposed on a side of the second insulation layer away from the substrate. A boundary of the barrier wall covers one of the connection portion and the third line segment.

### CROSS REFERENCE TO RELATED APPLICATIONS

This application claims the priority to Chinese Patent Application No. 202311357636.7, filed on Oct. 18, 2023. The entire disclosures of the above application are incorporated herein by reference.

### FIELD OF INVENTION

The present application relates to a field of display technologies, especially to an array substrate and a display panel.

### BACKGROUND OF INVENTION

In a reliability test of a liquid crystal display panel, one of reasons that a black screen occurs on the liquid crystal display panel is an electrical field occurs between a clock signal (CK) line and a low frequency clock signal (LC) line of a gate driver circuit unit (GOA) integrated on an array substrate. Under an effect of the electrical field, copper ions of the two signal lines are precipitated and spread horizontally, resulting in a short circuit between the clock signal line and the low frequency clock signal line disposed in the same layer.

### SUMMARY OF INVENTION

An embodiment of the present application provides an array substrate and a display panel that can lower a risk of a short circuit between a second signal line and a first signal line.

The embodiment of the present application provides an array substrate comprising a gate driver circuit unit, and the array substrate comprises:
a substrate;
a first signal line comprising a first line segment and a second line segment, wherein the first line segment is disposed on the substrate, and the second line segment comprises a connection portion and a wiring portion;
a first insulation layer covering the substrate and the first line segment, wherein at least one first via hole is defined in the first insulation layer;
a second signal line comprising a third line segment, wherein the third line segment and the second line segment are located in a same layer and are disposed adjacently on the first insulation layer, the connection portion is connected to the first line segment through the first via hole and overlaps the first line segment, and the wiring portion is connected to the connection portion;
a second insulation layer covering the first insulation layer, the third line segment, and the second line segment; and
a barrier wall disposed on a side of the second insulation layer away from the substrate and intersecting the third line segment;
wherein in an orthographic projection pattern of the array substrate, a boundary of the barrier wall does not simultaneously cover the connection portion and the third line segment.

Optionally, in some embodiments of the present application, in the orthographic projection pattern of the array substrate, and the barrier wall is located on an outer periphery of the second line segment.

Optionally, in some embodiments of the present application, in the orthographic projection pattern of the array substrate, the barrier wall is located on an outside of the first line segment away from the second line segment.

Optionally, in some embodiments of the present application, the array substrate comprises a gate driver circuit unit, the first signal line is a low frequency clock signal line, the second signal line is a clock signal line, the third line segment is connected to the gate driver circuit unit, and the wiring portion is connected to the gate driver circuit unit;
the second signal line further comprises a fourth line segment, the fourth line segment and the first line segment are located on a same layer and are spaced from each other on the substrate, and the first insulation layer covers the fourth line segment;
the fourth line segment is located on a side of the first line segment away from the gate driver circuit unit, at least one second via hole is defined in the first insulation layer, the second via hole exposes the fourth line segment, and the third line segment is connected to the fourth line segment through the second via hole; and
in the orthographic projection pattern of the array substrate, the barrier wall is located between the first line segment and the fourth line segment.

Optionally, in some embodiments of the present application, a distance between the wiring portion and the third line segment is greater than a distance between the connection portion and the third line segment.

Optionally, in some embodiments of the present application, in the orthographic projection pattern of the array substrate, the barrier wall completely covers the second line segment.

Optionally, in some embodiments of the present application, a distance between the wiring portion and the third line segment is greater than a distance between the connection portion and the third line segment; and in the orthographic projection pattern of the array substrate, the barrier wall at least completely covers the connection portion.

Optionally, in some embodiments of the present application, in the orthographic projection pattern of the array substrate, the barrier wall further completely covers the first line segment.

Optionally, in some embodiments of the present application, the array substrate comprises a gate driver circuit unit, the first signal line is a low frequency clock signal line, the second signal line is a clock signal line, the third line segment is connected to the gate driver circuit unit, and the wiring portion is connected to the gate driver circuit unit.

Optionally, in some embodiments of the present application, a hollow opening is defined in the first line segment, and in the orthographic projection pattern of the array substrate, at least a portion of the hollow opening is located between the second line segment and the third line segment; and
the first insulation layer covers the hollow opening to form a recess, at least one region of the recess is disposed between the second line segment and the third line segment.

Optionally, in some embodiments of the present application, the hollow opening is plural, each of the hollow openings extends along a short axis direction of the third line segment, and the hollow openings are arranged at intervals along a long axis direction of the third line segment.

Optionally, in some embodiments of the present application, the hollow opening extends along a long axis direction of the third line segment.

Optionally, in some embodiments of the present application, the at least one first via hole is located on a side of the first line segment near the gate driver circuit unit.

Optionally, in some embodiments of the present application, a distance between the second line segment and the third line segment is greater than or equal to 20.4 microns.

Optionally, in some embodiments of the present application, a thickness of the second insulation layer is greater than or equal to 1000 Å.

Optionally, in some embodiments of the present application, the array substrate further comprises a planarization layer, material of the planarization layer is organic material, the planarization layer covers the second insulation layer, and the barrier wall is disposed on a side of the planarization layer away from the substrate.

Optionally, in some embodiments of the present application, a thermal expansion coefficient of the planarization layer is less than a thermal expansion coefficient of the barrier wall, and is greater than a thermal expansion coefficient of the second insulation layer.

The embodiment of the present application also provides a display panel, comprising an opposite substrate, a liquid crystal layer, and the array substrate of any one of the above embodiments, and the liquid crystal layer is disposed between the opposite substrate and the array substrate, and the array substrate comprises:
a substrate;
a first signal line comprising a first line segment and a second line segment, wherein the first line segment is disposed on the substrate, and the second line segment comprises a connection portion and a wiring portion;
a first insulation layer covering the substrate and the first line segment, wherein at least one first via hole is defined in the first insulation layer;
a second signal line comprising a third line segment, wherein the third line segment and the second line segment are located in a same layer and are disposed adjacently on the first insulation layer, the connection portion is connected to the first line segment through the first via hole and overlaps the first line segment, and the wiring portion is connected to the connection portion;
a second insulation layer covering the first insulation layer, the third line segment, and the second line segment; and
a barrier wall disposed on a side of the second insulation layer away from the substrate and intersecting the third line segment;
wherein in an orthographic projection pattern of the array substrate, a boundary of the barrier wall does not simultaneously cover the connection portion and the third line segment.

Optionally, in some embodiments of the present application, in the orthographic projection pattern of the array substrate, and the barrier wall is located on an outer periphery of the second line segment.

Optionally, in some embodiments of the present application, in the orthographic projection pattern of the array substrate, the barrier wall is located on an outside of the first line segment away from the second line segment.

Optionally, in some embodiments of the present application, the array substrate comprises a gate driver circuit unit, the first signal line is a low frequency clock signal line, the second signal line is a clock signal line, the third line segment is connected to the gate driver circuit unit, and the wiring portion is connected to the gate driver circuit unit;
the second signal line further comprises a fourth line segment, the fourth line segment and the first line segment are located on a same layer and are spaced from each other on the substrate, and the first insulation layer covers the fourth line segment;
the fourth line segment is located on a side of the first line segment away from the gate driver circuit unit, at least one second via hole is defined in the first insulation layer, the second via hole exposes the fourth line segment, and the third line segment is connected to the fourth line segment through the second via hole; and
in the orthographic projection pattern of the array substrate, the barrier wall is located between the first line segment and the fourth line segment.

Optionally, in some embodiments of the present application, a distance between the wiring portion and the third line segment is greater than a distance between the connection portion and the third line segment.

The array substrate of the embodiment of the present application comprises a substrate, a first signal line, a first insulation layer, a second signal line, a second insulation layer, and a barrier wall. The first signal line comprises a first line segment and a second line segment. The first line segment is disposed on the substrate. The second line segment comprises a connection portion and a wiring portion. The first insulation layer covers the substrate and the first line segment. At least one first via hole is defined in the first insulation layer. The second signal line comprises a third line segment. The third line segment and the second line segment are in the same layer and are disposed adjacently on the first insulation layer. The third line segment is connected to a gate driver circuit unit. The connection portion is connected to the first line segment through the first via hole and overlaps the first line segment. An end of the wiring portion is connected to the connection portion, another end of the wiring portion is connected to the gate driver circuit unit. The second insulation layer covers the first insulation layer, the third line segment, and the second line segment. The barrier wall is disposed on a side of the second insulation layer away from the substrate. The barrier wall intersects the third line segment. In an orthographic projection pattern of the array substrate, a boundary of the barrier wall does not simultaneously cover the connection portion and the third line segment.

An array substrate of the present application employs the boundary of the barrier wall only covering one of the connection portion and the third line segment. Namely, in the orthographic projection pattern of the array substrate, the boundary of the barrier wall does not simultaneously divide the connection portion and the third line segment respectively. In other words, the barrier wall avoids the region between the connection portion and the third line segment such that thermal expansion stress of the barrier wall would not affect the second insulation layer of the region between the connection portion and the third line segment to lower the risk of cracks of the region between the connection portion and the third line segment to further lower the risk of a short circuit between the second signal line and the first signal line. Alternatively, the barrier wall completely covers the region between the connection portion and the third line segment such that the influence of thermal expansion stress of the barrier wall to the second insulation layer of the region become consistent to lower the risk of cracks of the second insulation layer of the region to further lower the risk of the short circuit between the second signal line and the first signal line.

### DESCRIPTION OF DRAWINGS

FIG. 1 is a schematic top structural view of an array substrate provided by the embodiment of the present application;

FIG. 2 is an enlarged view of an A portion in FIG. 1;

FIG. 3 is a schematic cross-sectional view along a CC line in FIG. 1;

FIG. 4 is another enlarged view of the A portion in FIG. 1;

FIG. 5 is a schematic top structural view of an array substrate provided by an embodiment 3 of the present application;

FIG. 6 is an enlarged view of an A portion in FIG. 5; and

FIG. 7 is a cross-sectional schematic view along a CC line in FIG. 5.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application. In addition, it should be understood that the specific embodiments described here are only used to illustrate and explain the present application, and are not used to limit the present application. In the present application, the used orientation terminologies such as “upper” and “lower”, when not specified to the contrary explanation, usually refer to the upper and lower states of the device in actual use or working conditions, specifically according to the direction of the figures in the drawings. Furthermore, “inner” and “outer” refer to the outline of the device. The terms “first,” “second,” “third,” etc., are used only as labels and do not impose any numerical requirements or establish a specific order.

The embodiment of the present application provides an array substrate and a display panel that would be described in detail as follows. It should be explained that a describing order of the following embodiments has no limit to a preferred order of the embodiments.

It should be explained that in the related technology of the array substrate, a gate driver circuit unit needs to receive a clock signal and a low frequency clock signal, and a voltage difference exists between the clock signal and the low frequency clock signal such that an electrical field occurs between the clock signal line and the low frequency clock signal line.

The clock signal line and the low frequency clock signal line are disposed in the same layer, and both are covered with a thinner inorganic insulation layer. Furthermore, to block an overflow of an alignment layer on the array substrate, usually a barrier wall is disposed on above the low frequency clock signal line, and the boundary of the barrier wall divides each of the low frequency clock signal line and the clock signal line into two partitions, which results in the inorganic insulation layer on the region between the low frequency clock signal line and the clock signal line being divided into two regions.

Because thermal expansion coefficient of the barrier wall is far greater than thermal expansion coefficient of the inorganic insulation layer, under heat, the region of the inorganic insulation layer disposed with the barrier wall and the region of the inorganic insulation layer disposed without a barrier wall receives different thermal expansion stresses such that a boundary between the two regions are cracked. Due to the crack of the inorganic insulation layer, metal ions in the clock signal line and the low frequency clock signal line, for example, copper ions, are precipitated and migrate and spread under an effect of an electrical field, finally resulting in a short circuit between the clock signal line and the low frequency clock signal line.

In particular, the low frequency clock signal line comprises a first line segment and a second line segment disposed in different layers and are connected to each other through a via hole. The clock signal line and the second line segment are disposed in the same layer and are spaced from each other. The inorganic insulation layer covers the second line segment and the clock signal line. an organic barrier wall is disposed on a portion of the inorganic insulation layer right corresponding to a region between the second line segment and the clock signal line. The second line segment and the clock signal line simultaneously extend through a side boundary of the organic barrier wall such that each of the second line segment and the clock signal line is divided into two portions. Because thermal expansion coefficients of the organic barrier wall and the inorganic insulation layer are different, under a certain temperature, portions of the second line segment and the clock signal line covered by the barrier wall would be influenced by thermal expansion stress, and portions thereof not covered by the barrier wall would not be influenced by the barrier wall thermal expansion such that a difference exists between stresses applied to two regions corresponding to the inorganic insulation layer, resulting in the crack of a boundary between the two regions. Therefore, under a sustaining effect of an electrical field, copper ions spread along a horizontal direction and heat thereof spreads outwardly radially, resulting in a short circuit between the clock signal line and the second line segment of the first signal line in the same layer.

An array substrate of the present application employs the boundary of the barrier wall only covering one of the connection portion and the third line segment. Namely, in the orthographic projection pattern of the array substrate, the boundary of the barrier wall does not simultaneously divide the connection portion and the third line segment respectively. In other words, the barrier wall avoids the region between the connection portion and the third line segment such that thermal expansion stress of the barrier wall would not affect the second insulation layer of the region between the connection portion and the third line segment to lower the risk of cracks of the region between the connection portion and the third line segment to further lower the risk of a short circuit between the second signal line and the first signal line. Alternatively, the barrier wall completely covers the region between the connection portion and the third line segment such that the influence of thermal expansion stress of the barrier wall to the second insulation layer of the region become consistent to lower the risk of cracks of the second insulation layer of the region to further lower the risk of the short circuit between the second signal line and the first signal line.

### Embodiment 1

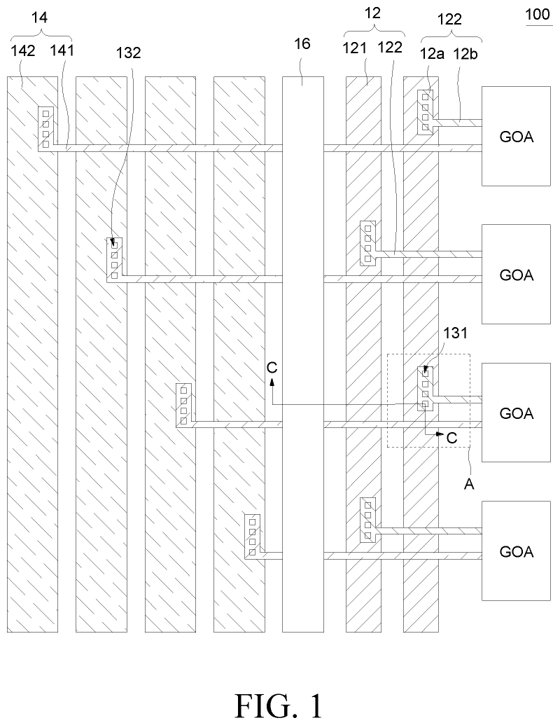

With reference to FIGS. 1 to 3, the embodiment of the present application provides an array substrate 100.

The array substrate 100 comprises a substrate 11, a first signal line 12, a first insulation layer 13, a second signal line 14, a second insulation layer 15, and a barrier wall 16.

The first signal line 12 comprises a first line segment 121 and a second line segment 122. The first line segment 121 is disposed on the substrate 11. The second line segment 122 comprises a connection portion 12a and a wiring portion 12b.

The first insulation layer 13 covers the substrate 11 and the first line segment 121. At least one first via hole 131 is defined in the first insulation layer 13.

The second signal line 14 comprises a third line segment 141. The third line segment 141 and the second line segment 122 are in the same layer and are disposed adjacently on the first insulation layer 13. The connection portion 12a is connected to the first line segment 121 through the first via hole 131 and overlaps the first line segment 121. The wiring portion 12b is connected to the connection portion 12a.

The second insulation layer 15 covers the first insulation layer 13, the third line segment 141, and the second line segment 122. The barrier wall 16 is disposed on a side of the second insulation layer 15 away from the substrate 11. The barrier wall 16 intersects the third line segment 141. In an orthographic projection pattern of the array substrate 100 (as shown in FIG. 1), a boundary of the barrier wall 16 does not simultaneously cover the connection portion 12a and the third line segment 141.

The array substrate 100 of the embodiment 1 of the present application employs the boundary of the barrier wall 16 does not simultaneously cover the connection portion 12a and the third line segment 141. The barrier wall 16 avoids the region between the connection portion 12a and the third line segment 141 such that thermal expansion stress of the barrier wall 16 would not influence the second insulation layer 15 of the region between the connection portion 12a and the third line segment 141, which lowers a risk of cracks of the second insulation layer 15 of the region between the connection portion 12a and the third line segment 141 to further reduce a risk of a short circuit between the second signal line 14 and the first signal line 12.

It should be explained that in the embodiment of the present application, the first signal line being a low frequency clock signal and the second signal line being a clock signal line are used as an example for explanation, but no limit is thereto, as long as the first signal line and the second signal line fulfill the above locations and structures.

The array substrate 100 comprises a gate driver circuit unit GOA. The third line segment 141 is connected to the gate driver circuit unit GOA. Another end of the wiring portion 12b is connected to the gate driver circuit unit GOA.

Optionally, the second line segment 122 and the third line segment 141 can be formed by the same mask process, material of both are the same.

Optionally, material of the barrier wall 16 can be transparent photoresist material. Material of the first insulation layer 13 and the second insulation layer 15 can be but is not limited to one of silicon oxide, silicon nitride, and silicon oxynitride.

Optionally, an extension direction of the first line segment 121 intersects an extension direction of the second line segment 122. For example, the extension direction of the first line segment 121 is perpendicular to the extension direction of the second line segment 122.

Optionally, in an orthographic projection pattern of the array substrate 100, the barrier wall 16 is located on an outer periphery of the second line segment 122.

Because the barrier wall 16 is located on the outer periphery of the second line segment 122 Therefore, all peripheries of the second line segment 122 are completely covered by the second insulation layer 15, which can block metal ions of the second line segment 122 from migrating outwardly to further lower a risk of the first signal line 12 contacting the second signal line 14 and resulting in a short circuit.

Optionally, in the orthographic projection pattern of the array substrate 100, the barrier wall 16 is located on an outside of the first line segment 121 away from the second line segment 122.

Disposing the barrier wall 16 on the outside of the first line segment 121 away from the second line segment 122, in an aspect, can prevent influence of a thermal expansion stress of the barrier wall 16 to the gate driver circuit unit GOA and guarantee stability and effectiveness of the gate driver circuit unit GOA, and in another aspect, can disposes the barrier wall 16 to be further away from the second line segment 122, which further reduces the risk of the short circuit between the first signal line 12 and the second signal line 14.

Optionally, the second signal line 14 further comprises a fourth line segment 142, the fourth line segment 142 and the first line segment 121 are in the same layer and are disposed on the substrate 11 at intervals. The first insulation layer 13 also covers the fourth line segment 142.

The fourth line segment 142 is located on a side of the first line segment 121 away from the gate driver circuit unit GOA. At least one second via hole 132 is defined in the first insulation layer 13. The second via hole 132 exposes the fourth line segment 142. the third line segment 141 is connected to the fourth line segment 142 through the second via hole 132.

In the orthographic projection pattern of the array substrate 100, the barrier wall 16 is located between the first line segment 121 and the fourth line segment 142.

It can be understood that because a voltage difference exists between a voltage inputted into the second signal line 14 and a voltage inputted into the first signal line 12, a parasitic capacitor occurs between the second signal line 14 and the first signal line 12.

Disposing the barrier wall 16 between the first line segment 121 and the fourth line segment 142 increases the distance between the first line segment 121 and the fourth line segment 142 to further achieve an effect of reducing a lateral parasitic capacitor.

Optionally, the first line segment 121 and the fourth line segment 142 can be formed by the same mask process, and both have the same material.

Optionally, an extension direction of the third line segment 141 intersects an extension direction of the fourth line segment 142. For example, the extension direction of the third line segment 141 is perpendicular to the extension direction of the fourth line segment 142.

Optionally, the array substrate 100 comprises a plurality of second signal lines 14 and at least one first signal line 12. The present embodiment uses four second signal lines 14 and two first signal lines as an example for description.

The fourth line segments 142 and the first line segment 121 are arranged along the extension direction of the third line segment 141. The third line segment 141 and the second line segment 122 are arranged alternately along the extension direction of the fourth line segment 142.

All of the second signal lines 14 are located on a side of the first signal line 12 away from the gate driver circuit unit GOA.

Optionally, an extension direction of the fourth line segment 142 is parallel to the extension direction of the first line segment 121.

Optionally, a thickness of the second insulation layer 15 is greater than or equal to 1000 Å, for example, the thickness can be 1000 Å, 1100 Å, 1200 Å, 1300 Å, 1400 Å, 1500 Å, 1600 Å, 1700 Å, 1800 Å, 1900 Å, 2000 Å, 2500 Å, 3000 Å, 3500 Å, or 4000 Å.

The embodiment of the present application, by increasing the thickness of the second insulation layer 15, improves the capability of the second insulation layer 15 resisting thermal expansion stress of the barrier wall 16, lowers the risk of the crack of the second insulation layer 15, and improves the capability of the second insulation layer 15 blocking metal ions from spreading and migrating.

It should be explained that compared to the array substrate of the related technology, under a condition that only the thickness of the second insulation layer 15 increases to 1000 Å but other conditions else are keep constant, during a display test of the display panel, the display panel displays normally and no short circuit exists between the second signal line 14 and the first signal line 12.

Optionally, a distance between the second line segment 122 and the third line segment 141 is greater than or equal to 20.4 microns, for example, the distance can be 20.4 microns, 20.5 microns, 20.6 microns, 20.7 microns, 20.8 microns, 20.9 microns, 21 microns, 22 microns, 23 microns, 24 microns, 25 microns, 26 microns, 27 microns, 28 microns, 29 microns, or 30 microns.

Compared to the related technology, setting the distance between the second line segment 122 and the third line segment 141 to be greater than or equal to 20.4 microns elongates a path along which metal ions spread and migrate, which further lower the risk of the short circuit between the second line segment 122 and the third line segment 141.

It should be explained that compared to the array substrate of the related technology, under a condition that only the distance between the third line segment 141 and the second line segment 122 is elongated to 20.4 microns but other conditions else are kept constant, during a display test of the display panel, the display panel displays normally and no short circuit exists between the second signal line 14 and the first signal line 12.

Optionally, a distance d1 between the wiring portion 12b and the third line segment 141 is greater than a distance d2 between the connection portion 12a and the third line segment 141.

Setting the distance d1 to be greater than the distance d2 increases the distance between the wiring portion 12b and the third line segment 141, which further increases the area of the second insulation layer 15 blocking spreading of the metal ions while elongating a path of spreading the metal ions to further achieve lowering the risk of the short circuit between the second signal line 14 and the first signal line 12.

Optionally, a width of an end portion of the wiring portion 12b connected to the connection portion 12a has a trend of gradual variation. Along a direction from the connection portion 12a to the gate driver circuit unit GOA, a width of the end portion of the wiring portion 12b connected to the connection portion 12a gradually decreases, which can lower the risk of cracks of the wiring portion 12b and the connection portion 12a while increasing the distance between the wiring portion 12b and the third line segment 141.

Optionally, the array substrate 100 further comprises a planarization layer 17, and material of the planarization layer 17 is organic material. The planarization layer 17 covers the second insulation layer 15. The barrier wall 16 is disposed on a side of the planarization layer 17 away from the substrate 11.

The planarization layer 17 used to cover the second insulation layer 15 provides a flat base surface for the barrier wall 16, which facilitates formation of the barrier wall 16 with a uniform height. Furthermore, the planarization layer 17 is organic material and can absorb a certain stress, which can ease an influence of thermal expansion stress of the barrier wall 16 to the second insulation layer 15 and lower a risk of cracks of the second insulation layer 15.

Optionally, a thermal expansion coefficient of the planarization layer 17 is less than a thermal expansion coefficient of the barrier wall 16, and is greater than a thermal expansion coefficient of the second insulation layer 15.

Thermal expansion coefficient of the planarization layer 17 ranges between thermal expansion coefficient of the barrier wall 16 and thermal expansion coefficient of the second insulation layer 15 such that a stress of the barrier wall 16 applied to the second insulation layer 15 is buffered, which lowers the influence of thermal expansion stress of the barrier wall 16 to the second insulation layer 15 to reduce the risk of the short circuit between the second signal line 14 and the first signal line 12.

Optionally, material of the planarization layer 17 can be but is not limited to a transparent photoresist.

Optionally, at least one the first via hole 131 is located on a side of the first line segment 121 near the gate driver circuit unit GOA.

Optionally, a plurality of the first via holes 131 are located on a side of the first line segment 121 near the gate driver circuit unit GOA, which along the extension direction of the first line segment 121 can reduce an overlapping area between the second line segment 122 and the third line segment 141 to further lower the risk of the short circuit between the second line segment 122 and the third line segment 141.

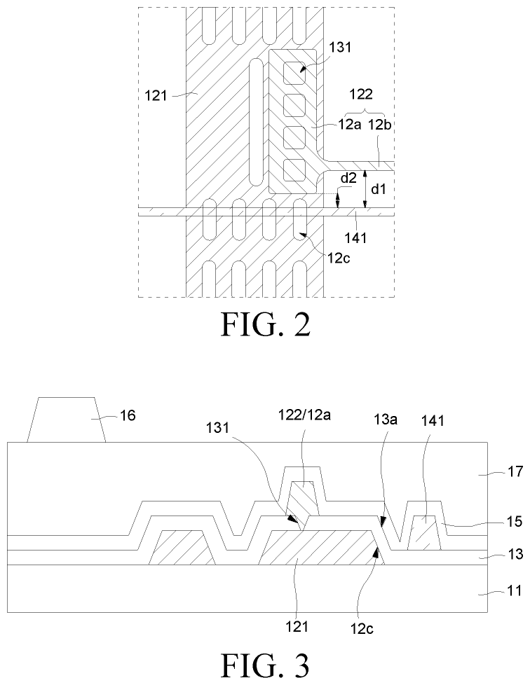

Optionally, with reference to FIGS. 2 and 3, a hollow opening 12c is defined in the first line segment 121. In the orthographic projection pattern of the array substrate 100, at least one portion of the hollow opening 12c is located between the second line segment 122 and the third line segment 141.

The first insulation layer 13 covers the hollow opening 12c to form a recess 13a, and at least one region of the recess 13a is disposed between the second line segment 122 and the third line segment 141.

The embodiment of the present application forms the hollow opening 12c in the first line segment 121, and sets at least one region of the hollow opening 12c between the second line segment 122 and the third line segment 141 such that the first insulation layer 13 covers the hollow opening 12c to form the recess 13a, which elongates the spreading path of the metal ions. Furthermore, in the region of the hollow opening 12c, the third line segment 141 and the second line segment 122 has a height difference, the first insulation layer 13 covers a sidewall of the hollow opening 12c to form a boss that can block the metal ions in the third line segment 141 from spreading to the second line segment 122. The second insulation layer 15 covers the recess 13a to increase the area of the second insulation layer 15 for blocking spreading of the metal ions.

Furthermore, disposing the hollow opening 12c facilitates light transmission for expediting curing of the frame sealant.

Optionally, a quantity of the hollow opening 12c is plural, each of the hollow openings 12c along a short axis direction of the third line segment 141. The hollow openings 12c are arranged at intervals along a long axis direction of the third line segment 141.

Disposing the hollow openings 12c drastically increases an effective area for interrupting spreading of the metal ions while improving light transmission, which further lowers a risk of a short circuit between the third line segment 141 and the second line segment 122.

The third line segment 141 extends and covers a plurality of the hollow openings 12c such that a portion of the third line segment 141 on the first line segment 121 [symbol] forms a relief structure, which improve a capability of the third line segment 141 resisting thermal expansion stress.

### Embodiment 2

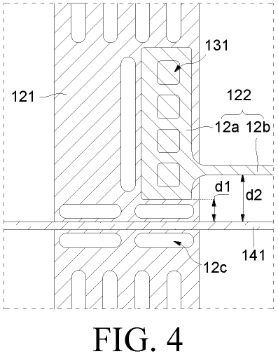

With reference to FIG. 4, a difference of the present embodiment 2 from the embodiment 1 is that: The hollow opening 12c extends along a long axis direction of the third line segment 141, and the hollow opening 12c is disposed between the third line segment 141 and the second line segment 122.

Compared to the solution of the embodiment 1 employing a plurality of vertical hollow openings 12c, adopting one elongated strip-like hollow opening 12c defined between the third line segment 141 and the second line segment 122 has a greater effective area for interrupting spreading of the metal ions, thus further lowering the risk of the short circuit of the third line segment 141 and the second line segment 122.

Along the extension direction of the first line segment 121, the third line segment 141 is disposed between adjacent two of the hollow opening 12c.

It should be explained that except for shape and location of the hollow opening 12c, the structures of the embodiment 2 are similar to or the same as those of the embodiment 1.

### Embodiment 3

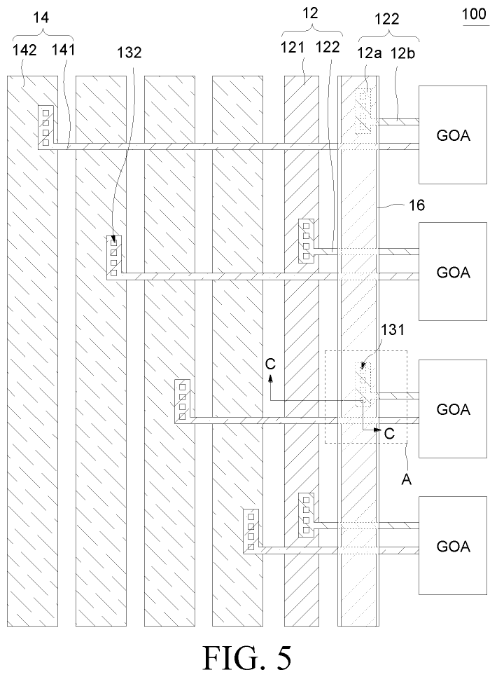

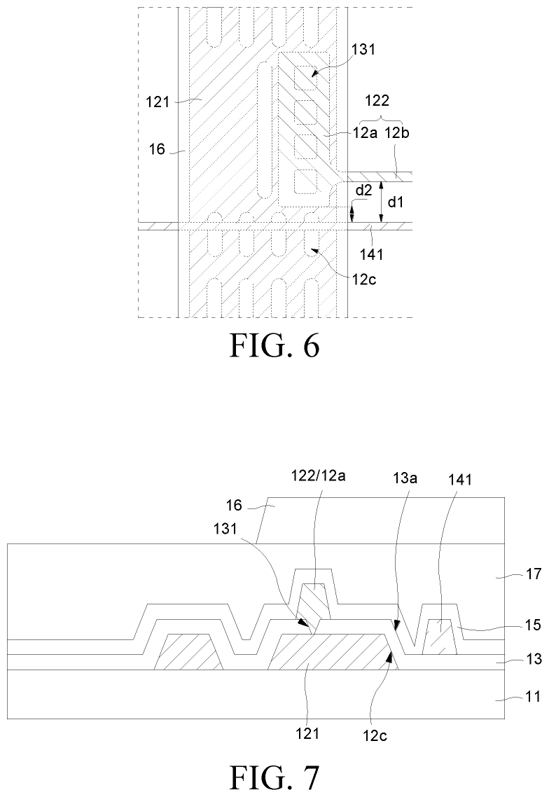

With reference to FIGS. 5 to 7, a difference of the present embodiment from the embodiment 1 and the embodiment 2 is a location of the barrier wall 16.

In particular, the distance d1 between the wiring portion 12b and the third line segment 141 is greater than the distance d2 between the connection portion 12a and the third line segment 141. In the orthographic projection pattern of the array substrate 100, the barrier wall 16 at least completely covers the connection portion 12a.

The array substrate 100 of the present embodiment 3 employs the boundary of the barrier wall 16 only covering one of the connection portion 12a and the third line segment 141. The barrier wall 16 completely covers the connection portion 12a and the third line segment 141 along the extension direction of the first line segment 121. The barrier wall 16 covers a region between the connection portion 12a and the third line segment 141 such that thermal expansion stress of the barrier wall 16 to the second insulation layer 15 of the region becomes consistent, thus lowering the risk of crack of the second insulation layer 15 of the region due to the non-uniform stress to further lower the risk of the short circuit between the second signal line 14 and the first signal line 12.

Optionally, in the orthographic projection pattern of the array substrate 100, the barrier wall 16 further completely covers the first line segment 121.

The barrier wall 16 completely covers the first line segment 121 to enlarge a contact area between the barrier wall 16 and the planarization layer 17 and improve stability.

Second, because a capacitor is formed by the first line segment 121 and a common electrode on the color filter substrate, the barrier wall 16 completely covering the first line segment 121 can improve uniformity and stability of the capacitor.

In another structure of the present embodiment, in the orthographic projection pattern of the array substrate 100, the barrier wall 16 completely covers the second line segment 122.

It should be explained that structures of the present embodiment 3 are similar to or the same as those in the embodiment 1 and the embodiment 2 except for a location of the barrier wall 16 of the present embodiment 3.

### Embodiment 4

The embodiment of the present application also provides a display panel comprising an opposite substrate, a liquid crystal layer, and the array substrate 100 of any one of the above embodiments. The liquid crystal layer is disposed between the opposite substrate and the array substrate 100.

The array substrate of the embodiment of the present application comprises a substrate, a first signal line, a first insulation layer, a second signal line, a second insulation layer, and a barrier wall. The first signal line comprises a first line segment and a second line segment. The first line segment is disposed on the substrate. The second line segment comprises a connection portion and a wiring portion. The first insulation layer covers the substrate and the first line segment. At least one first via hole is defined in the first insulation layer. The second signal line comprises a third line segment. The third line segment and the second line segment are in the same layer and are disposed adjacently on the first insulation layer. The third line segment is connected to a gate driver circuit unit. The connection portion is connected to the first line segment through the first via hole and overlaps the first line segment. An end of the wiring portion is connected to the connection portion, another end of the wiring portion is connected to the gate driver circuit unit. The second insulation layer covers the first insulation layer, the third line segment, and the second line segment. The barrier wall is disposed on a side of the second insulation layer away from the substrate. The barrier wall intersects the third line segment. In an orthographic projection pattern of the array substrate, a boundary of the barrier wall does not simultaneously cover the connection portion and the third line segment.

An array substrate of the present application employs the boundary of the barrier wall only covering one of the connection portion and the third line segment. Namely, in the orthographic projection pattern of the array substrate, the boundary of the barrier wall does not simultaneously divide the connection portion and the third line segment respectively. In other words, the barrier wall avoids the region between the connection portion and the third line segment such that thermal expansion stress of the barrier wall would not affect the second insulation layer of the region between the connection portion and the third line segment to lower the risk of cracks of the region between the connection portion and the third line segment to further lower the risk of a short circuit between the second signal line and the first signal line. Alternatively, the barrier wall completely covers the region between the connection portion and the third line segment such that the influence of thermal expansion stress of the barrier wall to the second insulation layer of the region become consistent to lower the risk of cracks of the second insulation layer of the region to further lower the risk of the short circuit between the second signal line and the first signal line.

It should be explained that the structure of the array substrate of the display panel of the embodiment of the present application is similar to or the same as the structure of the array substrate 100 in any one of embodiments 1-3.

The array substrate and the display panel provided by the embodiment of the present application are described in detail as above. In the specification, the specific examples are used to explain the principle and embodiment of the present application. The above description of the embodiments is only used to help understand the method of the present application and its spiritual idea. Meanwhile, for those skilled in the art, according to the present idea of invention, changes will be made in specific embodiment and application. In summary, the contents of this specification should not be construed as limiting the present application.

What is claimed is:

1. An array substrate, comprising:
a substrate;
a first signal line comprising a first line segment and a second line segment, wherein the first line segment is disposed on the substrate, and the second line segment comprises a connection portion and a wiring portion;
a first insulation layer covering the substrate and the first line segment, wherein at least one first via hole is defined in the first insulation layer;
a second signal line comprising a third line segment, wherein the third line segment and the second line segment are located in a same layer and are disposed adjacently on the first insulation layer, the connection portion is connected to the first line segment through the first via hole and overlaps the first line segment, and the wiring portion is connected to the connection portion;
a second insulation layer covering the first insulation layer, the third line segment, and the second line segment; and
a barrier wall disposed on a side of the second insulation layer away from the substrate and intersecting the third line segment;
wherein in an orthographic projection pattern of the array substrate, a boundary of the barrier wall does not simultaneously cover the connection portion and the third line segment.

2. The array substrate according to claim 1, wherein in the orthographic projection pattern of the array substrate, and the barrier wall is located on an outer periphery of the second line segment.

3. The array substrate according to claim 2, wherein in the orthographic projection pattern of the array substrate, the barrier wall is located on an outside of the first line segment away from the second line segment.

4. The array substrate according to claim 3, wherein
the array substrate comprises a gate driver circuit unit, the first signal line is a low frequency clock signal line, the second signal line is a clock signal line, the third line segment is connected to the gate driver circuit unit, and the wiring portion is connected to the gate driver circuit unit;
the second signal line further comprises a fourth line segment, the fourth line segment and the first line segment are located on a same layer and are spaced from each other on the substrate, and the first insulation layer covers the fourth line segment;
the fourth line segment is located on a side of the first line segment away from the gate driver circuit unit, at least one second via hole is defined in the first insulation layer, the second via hole exposes the fourth line segment, and the third line segment is connected to the fourth line segment through the second via hole; and
in the orthographic projection pattern of the array substrate, the barrier wall is located between the first line segment and the fourth line segment.

5. The array substrate according to claim 2, wherein a distance between the wiring portion and the third line segment is greater than a distance between the connection portion and the third line segment.

6. The array substrate according to claim 1, wherein
a distance between the wiring portion and the third line segment is greater than a distance between the connection portion and the third line segment; and
in the orthographic projection pattern of the array substrate, the barrier wall at least completely covers the connection portion.

7. The array substrate according to claim 6, wherein in the orthographic projection pattern of the array substrate, the barrier wall further completely covers the first line segment.

8. The array substrate according to claim 7, wherein the array substrate comprises a gate driver circuit unit, the first signal line is a low frequency clock signal line, the second signal line is a clock signal line, the third line segment is connected to the gate driver circuit unit, and the wiring portion is connected to the gate driver circuit unit.

9. The array substrate according to claim 1, wherein
a hollow opening is defined in the first line segment, and in the orthographic projection pattern of the array substrate, at least a portion of the hollow opening is located between the second line segment and the third line segment; and
the first insulation layer covers the hollow opening to form a recess, at least one region of the recess is disposed between the second line segment and the third line segment.

10. The array substrate according to claim 9, wherein the hollow opening is plural, each of the hollow openings extends along a short axis direction of the third line segment, and the hollow openings are arranged at intervals along a long axis direction of the third line segment.

11. The array substrate according to claim 9, wherein the hollow opening extends along a long axis direction of the third line segment.

12. The array substrate according to claim 8, wherein the at least one first via hole is located on a side of the first line segment near the gate driver circuit unit.

13. The array substrate according to claim 1, wherein a distance between the second line segment and the third line segment is greater than or equal to 20.4 microns.

14. The array substrate according to claim 1, wherein a thickness of the second insulation layer is greater than or equal to 1000 Å.

15. The array substrate according to claim 1, wherein the array substrate further comprises a planarization layer, material of the planarization layer is organic material, the planarization layer covers the second insulation layer, and the barrier wall is disposed on a side of the planarization layer away from the substrate.

16. A display panel, comprising an opposite substrate, a liquid crystal layer, and an array substrate, wherein the liquid crystal layer is disposed between the opposite substrate and the array substrate, wherein the array substrate comprises:
a substrate;
a first signal line comprising a first line segment and a second line segment, wherein the first line segment is disposed on the substrate, and the second line segment comprises a connection portion and a wiring portion;
a first insulation layer covering the substrate and the first line segment, wherein at least one first via hole is defined in the first insulation layer;
a second signal line comprising a third line segment, wherein the third line segment and the second line segment are located in a same layer and are disposed adjacently on the first insulation layer, the connection portion is connected to the first line segment through the first via hole and overlaps the first line segment, and the wiring portion is connected to the connection portion;
a second insulation layer covering the first insulation layer, the third line segment, and the second line segment; and
a barrier wall disposed on a side of the second insulation layer away from the substrate and intersecting the third line segment;
wherein in an orthographic projection pattern of the array substrate, a boundary of the barrier wall does not simultaneously cover the connection portion and the third line segment.

17. The display panel according to claim 16, wherein in the orthographic projection pattern of the array substrate, and the barrier wall is located on an outer periphery of the second line segment.

18. The display panel according to claim 17, wherein in the orthographic projection pattern of the array substrate, the barrier wall is located on an outside of the first line segment away from the second line segment.

19. The display panel according to claim 18, wherein
the array substrate comprises a gate driver circuit unit, the first signal line is a low frequency clock signal line, the second signal line is a clock signal line, the third line segment is connected to the gate driver circuit unit, and the wiring portion is connected to the gate driver circuit unit;
the second signal line further comprises a fourth line segment, the fourth line segment and the first line segment are located on a same layer and are spaced from each other on the substrate, and the first insulation layer covers the fourth line segment;
the fourth line segment is located on a side of the first line segment away from the gate driver circuit unit, at least one second via hole is defined in the first insulation layer, the second via hole exposes the fourth line segment, and the third line segment is connected to the fourth line segment through the second via hole; and
in the orthographic projection pattern of the array substrate, the barrier wall is located between the first line segment and the fourth line segment.

20. The display panel according to claim 17, wherein a distance between the wiring portion and the third line segment is greater than a distance between the connection portion and the third line segment.
